(19) United States
(12) Patent Application Publication
(10) Pub. No.: US 2018/0359878 A1
(43) Pub. Date: Dec. 13, 2018

(54) SERVER SYSTEM

(71) Applicants: INVENTEC (PUDONG) TECHNOLOGY CORPORATION, Shanghai City (CN); INVENTEC CORPORATION, Taipei City (TW)

(72) Inventors: Ji-Peng XU, Shanghai City (CN); Hui ZHU, Shanghai City (CN)

(73) Assignees: INVENTEC (PUDONG) TECHNOLOGY CORPORATION, Shanghai City (CN); INVENTEC CORPORATION, Taipei City (TW)

(21) Appl. No.: 15/634,715

(22) Filed: Jun. 27, 2017

(30) Foreign Application Priority Data
Jun. 12, 2017 (CN) 201710445267.5

(51) Int. Cl. H05K 7/20; H05K 7/14

(52) U.S. Cl. CPC H05K 7/20136; G06F 1/266; H05K 7/1492; H05K 7/1489

(57) ABSTRACT

A server system includes a server frame, a host server, a GPU expander board, a first fan module and a power supply. The server frame has a host server accommodating space and a graphic processing module space. The graphic processing module space is located above the host server accommodating space. The host server is removably disposed in the host server accommodating space. The GPU expander board is located in the graphic processing module space and located above the host server. The first fan module is located in the graphic processing module space, is located at a side of the GPU expander board, and is located above the host server. The power supply unit is located in the graphic processing module space, is located above another side of the GPU expander board, and is configured to provide electricity to the first fan module and the GPU expander board.

### CROSS-REFERENCE TO RELATED APPLICATIONS

This non-provisional application claims priority under 35 U.S.C. § 119(a) on Patent Application No(s). 201710445267.5 filed in China on Jun. 12, 2017, the entire contents of which are hereby incorporated by reference.

### BACKGROUND OF THE INVENTION

### Technical Field of the Invention

The disclosure relates to a server system, more particularly to a server system including a GPU expander board.

### Description of the Related Art

Artificial intelligence (AI) can make machines work and react like humans. Deep learning is a fast-growing field of artificial intelligence, and is especially used to make computers more similar to the human brain. Graphic processing units (GPU) have far more processor cores than central processing units (CPU), and are specifically for processing complicated algorithms, so GPUs are able to process parallel workloads more efficiently than CPUs, and are well-suited for deep learning. As a result, current deep learning models are relying on GPUs.

Therefore, server developers put lots of effort into developing a server capable of carrying GPUs in order to meet the requirements of the market.

### SUMMARY OF THE INVENTION

One embodiment of the disclosure provides a server system including a server frame, a host server, a GPU expander board, a first fan module and a power supply. The server frame has a host server accommodating space and a graphic processing module space. The graphic processing module space is located above the host server accommodating space. The host server is removably disposed in the host server accommodating space. The GPU expander board is located in the graphic processing module space and located above the host server. The first fan module is located in the graphic processing module space, is located at a side of the GPU expander board, and is located above the host server. The power supply unit is located in the graphic processing module space, is located above another side of the GPU expander board, and is configured to provide electricity to the first fan module and the GPU expander board.

### BRIEF DESCRIPTION OF THE DRAWINGS

The present disclosure will become more fully understood from the detailed description given hereinbelow and the accompanying drawings which are given by way of illustration only and thus are not limitative to the present disclosure and wherein:

FIG. 1 is an exploded view of a server system according to an embodiment of the disclosure;

FIG. 2 is an exploded view of the server system in FIG. 1;

FIG. 3 is a cross-sectional view of the server system in FIG. 1;

FIG. 4 is a cross-sectional view of the server system in FIG. 1 showing the arrangement of the inner space of the server frame; and

FIG. 5 is a rear view of the server system in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the following embodiments are disclosed by the figures, and some practical details are described in the following paragraphs, but the present disclosure is not limited thereto. Furthermore, for the purpose of illustration, some of the structures and components in the figures are simplified, and wires, lines or buses are omitted in some of the figures.

Moreover, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

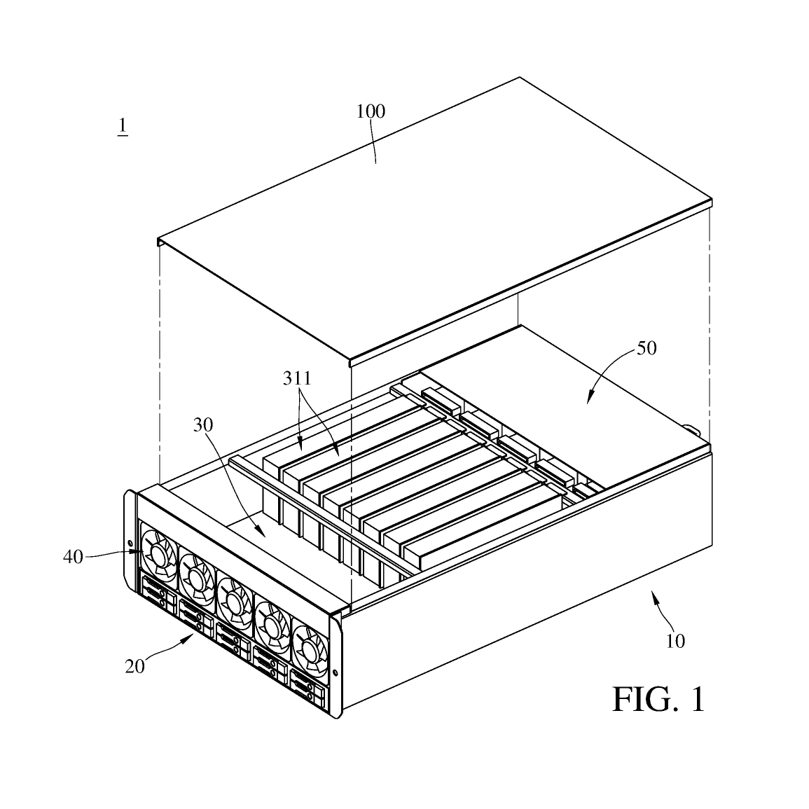

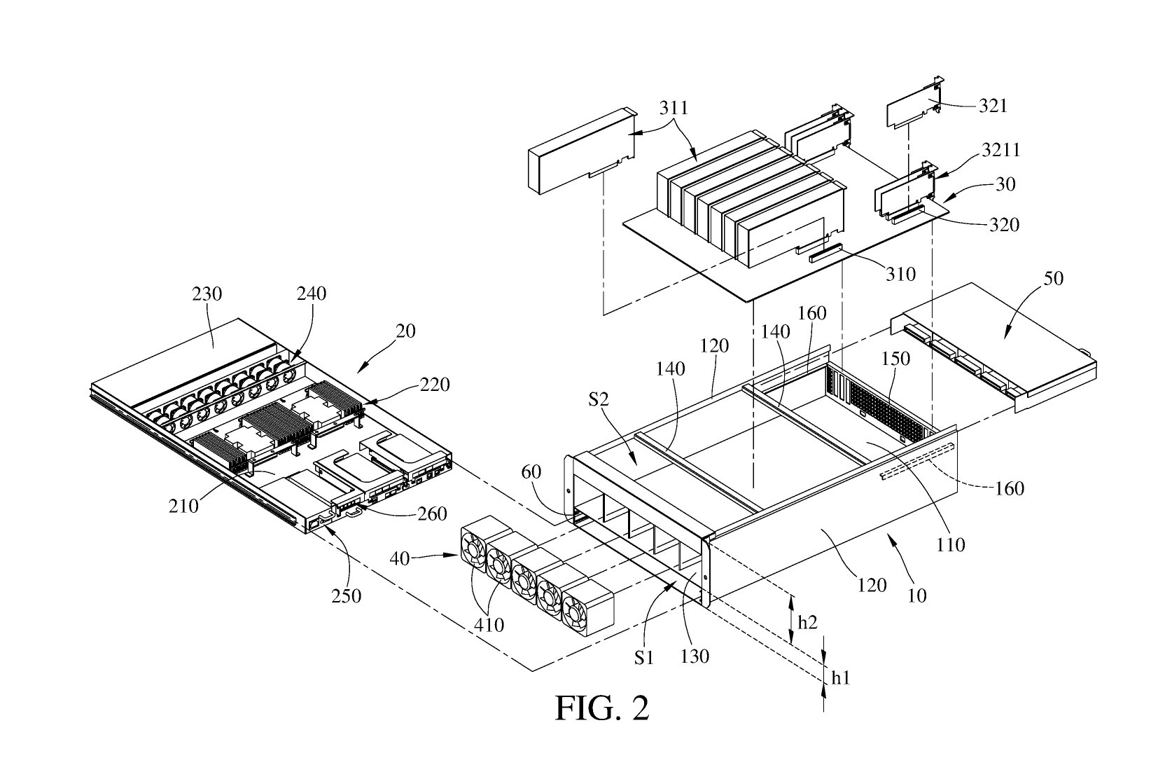

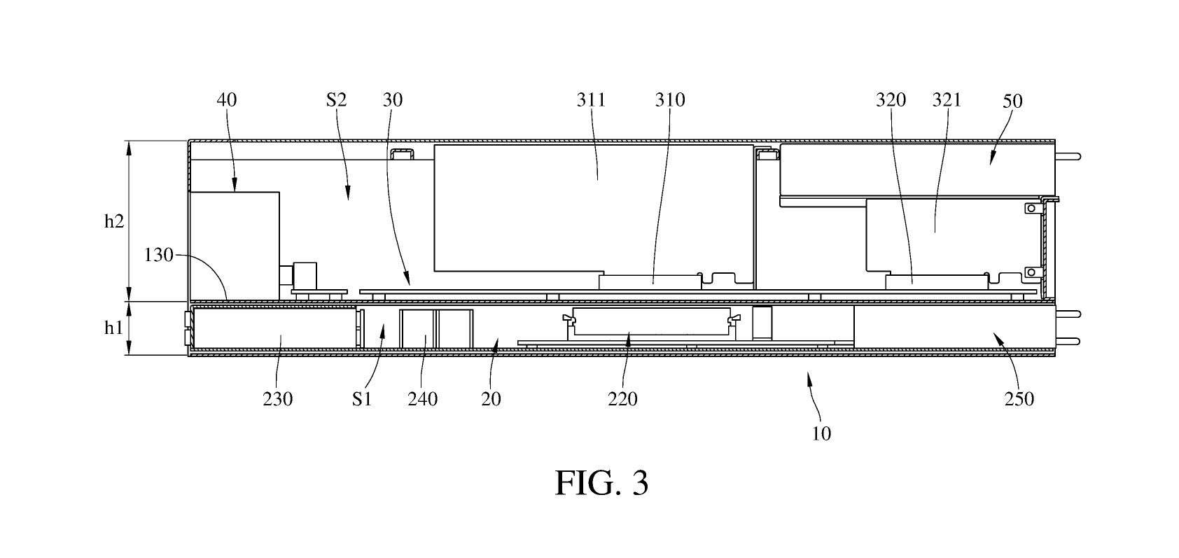

Please refer to FIGS. 1-3, FIG. 1 is an exploded view of a server system according to an embodiment of the disclosure, FIG. 2 is an exploded view of the server system in FIG. 1, and FIG. 3 is a cross-sectional view of the server system in FIG. 1.

This embodiment provides a server system 1. The server system 1 includes a server frame 10, a host server 20, a GPU expander board 30, a first fan module 40 and a power supply unit 50.

The server frame 10 includes a top plate 100, a bottom plate 110, two side plates 120, a partition plate 130, two bridges 140 and a back plate 150. For the purpose of clear illustration in FIG. 2, the top plate 100 is not shown in the drawing.

The two side plates 120 are respectively disposed on two opposite sides of the bottom plate 110. The partition plate 130 is located between and connected to the side plates 120, and is spaced apart from the bottom plate 110. The two bridges 140 are located between and connected to the two side plates 120, and are located at a side of the side plates 120 which is away from the bottom plate 110. The bridges 140 are capable of enhancing the structural strength of the server frame 10. However, the bridges 140 are optional. In addition, the present disclosure is not limited to the quantity of the bridges 140. The back plate 150 is disposed on the rear end of the bottom plate 110, and is located between and connected to the two side plates 120. The top plate 100 is disposed at the side of the two side plates 120, which is away from the bottom plate 110.

It is noted that, in this embodiment, a space between the side plates 120 and the bottom plate 110 is divided into a host server accommodating space Si and a graphic processing module space S2 by the partition plate 130. In detail, the host server accommodating space Si is located between the two side plates 120 and the bottom surface of the partition plate 130, and the graphic processing module space S2 is located between the two side plates 120 and the top surface of the partition plate 130. That is, the graphic processing module space S2 is located above the host server accommodating space S1.

Also, in this embodiment and other embodiments, the height of the server frame 10 is 4U, the height h1 of the host server accommodating space S1 is 1U, and the height h2 of the graphic processing module space S2 is 3U.

The host server 20 is removably disposed in the host server accommodating space S1. Hence, it is understood that the host server 20 is a server with height of 1U. In detail, the host server 20 includes a tray 200, a motherboard 210, a plurality of processing modules 220, a plurality of hard disks 230, a second fan module 240, a power port 250 and a plurality of first input/output connectors 260. The motherboard 210 is disposed on the tray 200. The hard disks 230 and the second fan module 240 are disposed on the tray 200 and connected to the motherboard 210. The processing modules 220, the power port 250 and the first input/output connectors 260 are disposed on the motherboard 210. Therefore, the aforementioned components of the host server 20 make it become a self-hosted server to the server system 1, but the present disclosure is not limited thereto. In some other embodiments, the host server 20 may be a host server to another server system. In addition, the quantities of the processing modules 220, the hard disks 230 and the first input/output connectors 260 may be adjusted according to actual requirements, the present disclosure is not limited thereto.

In this embodiment, the server system 1 further includes a rail set 60 located in the host server accommodating space Si and disposed on the side plates 120 of the server frame 10. Two opposite sides of the tray 200 are respectively disposed with two inner rail structures (not numbered) corresponding to the rail set 60, thereby allowing the tray 200 to be slide on the rail set 60. Accordingly, the host server 20 is able to be moved with respect to the server frame 10.

The GPU expander board 30 is located in the graphic processing module space S2 and disposed on the partition plate 130. In detail, the GPU expander board 30 has a plurality of

GPU slots 310 and a plurality of additional slots 320. The GPU slots 310 are configured for the graphic processing units (also called GPU) 311 to be inserted. The graphic processing units 311 are processors specialized for processing graphics. The additional slots 320 are configured for the insertion of the additional cards 321. The additional cards 321 are, for example, Network Interface Cards (NICs) or another additional card with connector for Mini SAS wire (SFF-8644). In this embodiment, the GPU expander board 30 has eight GPU slots 310 for eight graphic processing units 311 to be inserted, which is beneficial for improving the ability of deep learning to tackle more complex tasks. However, the present disclosure is not limited to the quantity of the GPU slots 310. In addition, each of the additional cards 321 has a second input/output connector 3211. The present disclosure is also not limited to the quantity of the additional slots 320 or the type of the additional card to be inserted. As shown in figures, it is understood that the server frame 10 provides a space with a height of 3U to accommodate the GPU expander board 30 and various electrical components thereon (e.g. the graphic processing units 311 and the additional cards 321).

The first fan module 40 is located in the graphic processing module space S2, and is disposed at a side of the partition plate 130 which is away from the back plate 150. In detail, the first fan module 40 includes five fans 410 to cool the electrical components inside the graphic processing module space S2. However, the present disclosure is not limited to the quantity of the fans 410. In some other embodiments, the quantity of the fans 410 may be less than or over five.

The power supply unit 50 is located in the graphic processing module space S2, and is located at a side of the side plates 120 which is close to the back plate 150. In detail, in this embodiment, the server frame 10 further includes a pair of brackets 160 which are respectively disposed on the side plates 120. The brackets 160 are spaced apart from the partition plate 130, and are located at a side of the side plates 120 which is close to the back plate 150. The power supply unit 50 is disposed on the brackets 160 so as to be located above the partition plate 130.

In addition, in this embodiment, the power supply unit 50 may be electrically connected to the aforementioned electrical components (e.g. the GPU expander board 30 and the first fan module 40) of the server system 1 through an inner cable (not shown) to provide electricity to them.

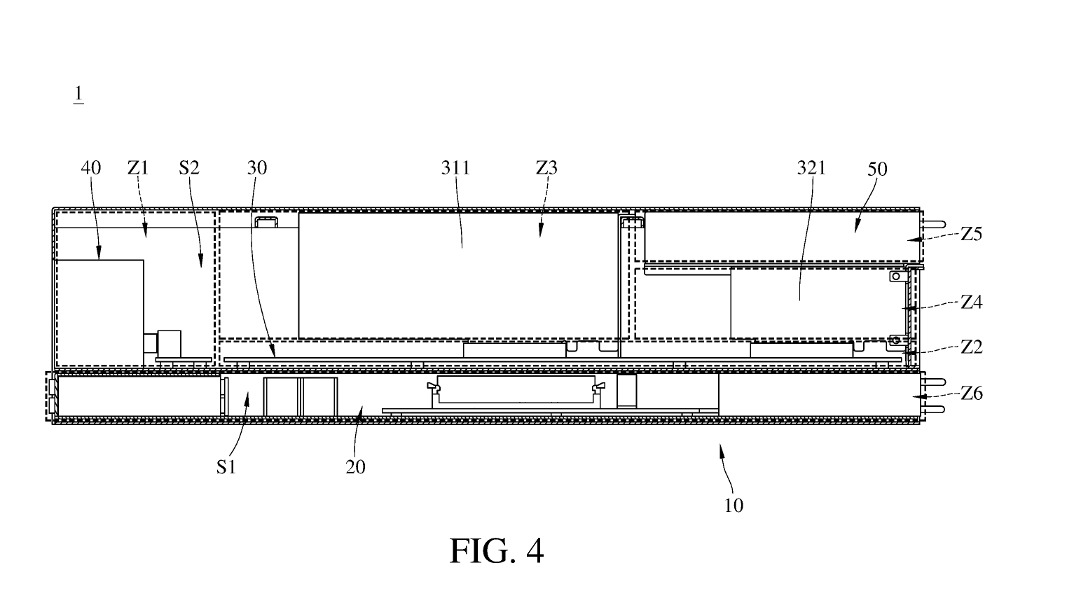

Then, please refer to FIG. 4. FIG. 4 is also a cross-sectional view similar to FIG. 3 but configured to show the arrangement of the aforementioned components inside the server frame 10.

As shown in FIG. 4, an area Z1 for accommodating the first fan module 40 is located at the front side of the server frame 10; an area Z2 for accommodating the GPU expander board 30 is located at the inner side of the area Z1; an area Z3 for accommodating the graphic processing units 311 is located at the top side of the area Z2 and the inner side of the area Z1; an area Z4 for accommodating the additional cards 321 is located at the top side of the area Z2, and is located a side of the area Z3 which is away from the area Z1 and at the rear side of the server frame 10; and an area Z5 for accommodating the power supply unit 50 is located at the rear side of the server frame 10 and the top side of the area Z4. The areas Z1 to Z5 are all located inside the graphic processing module space S2. Then, an area Z6 (i.e. the host server accommodating space S1) for accommodating the host server 20 is located at the bottom side of the area Z1 and the area Z2; that is, the area Z6 is located at the most bottom side of the server frame 10.

The arrangement of the components inside the server system 1 is well organized. Accordingly, the replacement of components in each area won't obstruct each other, which is beneficial for upgrading them.

In addition, in this embodiment, the host server 20, the first fan module 40, and the power supply unit 50 are disposed on the server frame 10 via a tool-less manner, which is beneficial for maintaining them.

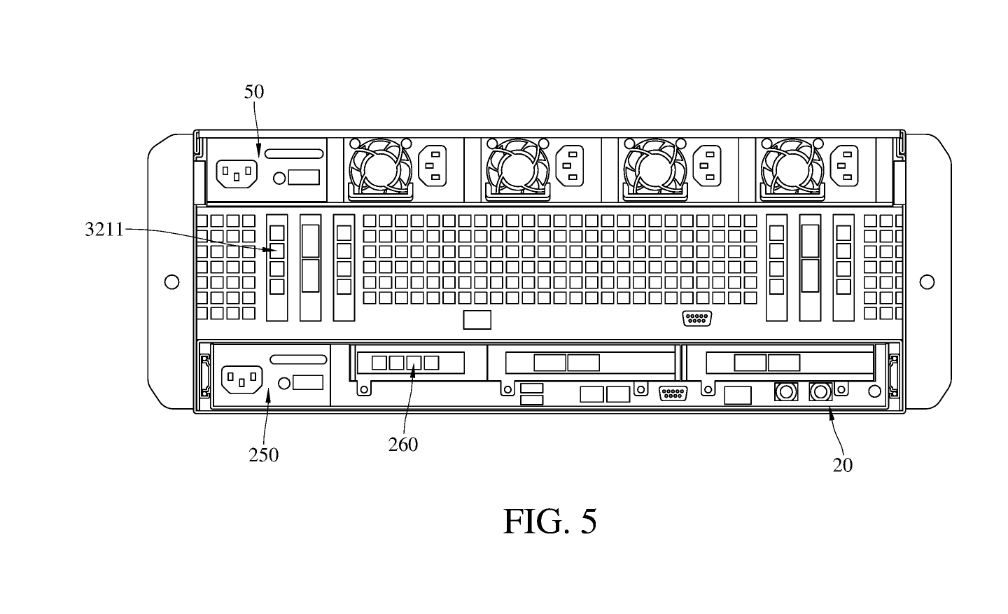

Then, please refer to FIG. 5, which is a rear view of the server system in FIG. 1.

In this embodiment, due to the organized arrangement of the inner space of the server frame 10, the power supply unit 50 and the second input/output connector 3211 inside the graphic processing module space S2 and the power port 250 and the first input/output connectors 260 of the host server 20 inside the host server accommodating space Si are all located in an area close to the rear end of the server frame 10. Therefore, the host server 20 is able to get electricity from the power supply unit 50 via an external cable (not shown) which is located outside the server frame 10. In addition, the host server 20 is able to be connected to the second input/output connectors 3211 of the additional cards 321 via another external cable (not shown) for signal communication, but the present disclosure is not limited thereto. The host server 20 maybe a self-hosted server to the server system 1 or a host server to another server system, and thus, in some other embodiments, there maybe no signal connection between the host server 20 and the graphic processing units 311 in the same server system. In addition, the server system 1 is adapted to be connected to an external power source (not shown), and the external power source is able to provide electricity to the host server 20.

According to the server system as discussed above, the inner space of the server frame divided into the host server accommodating space and the graphic processing module space is presented in an organized manner. Also, the graphic processing module space is located above the host server accommodating space, so the insertion and the taking out of graphic processing units and host server won't obstruct each other; therefore, the arrangement of the host server accommodating space and the graphic processing module space is beneficial for disposing and replacing components therein. Furthermore, the graphic processing module space is above the host server accommodating space, thereby allowing the graphic processing module space to have a larger width to dispose the greatest amount of the graphic processing units possible to improve the ability of deep learning.

In addition, the host server, in the host server accommodating space, cooperating with the power supply unit and the first fan module is capable of making the server system to become an independent operating server system.

Moreover, the host server, the first fan module and the power supply unit are able to be disposed on the server frame via tool-less manner, which is beneficial for maintaining them.

1. A server system, comprising:
a server frame having a host server accommodating space and a graphic processing module space, and the graphic processing module space located above the host server accommodating space;
a host server removably disposed in the host server accommodating space;
a GPU expander board located in the graphic processing module space and located above the host server;
a first fan module located in the graphic processing module space, located at a side of the GPU expander board, and located above the host server; and
a power supply unit located in the graphic processing module space, located above another side of the GPU expander board, and configured to provide electricity to the first fan module and the GPU expander board.

2. The server system according to claim 1, wherein the GPU expander board has a plurality of GPU slots and at least one additional slot, the plurality of GPU slots are closer to the first fan module than the plurality of additional slots to the first fan module, and the at least one additional slot is located below the power supply unit.

3. The server system according to claim 1, wherein the host server accommodating space has at least one first input/output connector, the graphic processing module space has at least one second input/output connector, and the at least one first input/output connector is electrically connectable to the at least one second input/output connector.

4. The server system according to claim 1, wherein the server frame comprises a bottom plate, two side plates and a partition plate, the two side plates are respectively disposed on two opposite sides of the bottom plate, the partition plate is located between and connected to the two side plates and spaced apart from the bottom plate, and a space between the side plates and the bottom plate is divided into the host server accommodating space and the graphic processing module space by the partition plate.

5. The server system according to claim 4, wherein the server frame further comprises at least one bridge located between and connected to the two side plates, and located in the graphic processing module space.

6. The server system according to claim 4, wherein the server frame further comprises a top plate disposed on a side of the two side plates which is away from the bottom plate.

7. The server system according to claim 1, wherein the host server comprises a motherboard, at least one processing module, at least one hard disk, a second fan module and a power port, the at least one processing module, the at least one hard disk, the second fan module and the power port are connected to the motherboard, and the power port is located below the power supply unit.

8. The server system according to claim 7, further comprising a rail set disposed on the server frame, the host server further comprising a tray, the motherboard, the at least one processing module, the at least one hard disk, the second fan module and the power port disposed on the tray, and the tray removably disposed on the server frame through the rail set.

9. The server system according to claim 7, further comprising an external cable located outside the server frame, and the power port of the host server electrically connectable to the power supply unit through the external cable.

10. The server system according to claim 1, further comprising an inner cable, the GPU expander board electrically connectable to the power supply unit through the inner cable.
